(19) United States
(12) Patent Application Publication
(10) Pub. No.: US 2025/0070063 A1
(43) Pub. Date: Feb. 27, 2025

(54) SEMICONDUCTOR DEVICE

(71) Applicant: Nuvoton Technology Corporation Japan, Kyoto (JP)

(72) Inventors: Hironao NAKAMURA, Kyoto (JP); Akira KIMURA, Kyoto (JP); Munehiro EGUCHI, Kyoto (JP); Takashi YUI, Kyoto (JP)

(21) Appl. No.: 18/942,018

(22) Filed: Nov. 8, 2024

Related U.S. Application Data
(63) Continuation of application No. PCT/JP2023/045572, filed on Dec. 19, 2023.
(60) Provisional application No. 63/491,332, filed on Mar. 21, 2023.

(51) Int. Cl. H01L 23/00; H01L 29/417

(52) U.S. Cl. CPC H01L 24/06; H01L 24/05; H01L 24/13; H01L 24/14; H01L 29/41741; H01L 2224/05015; H01L 2224/0603; H01L 2224/06152; H01L 2224/06153; H01L 2224/13005; H01L 2224/1403; H01L 2224/14152; H01L 2224/14153; H01L 2924/13091; H01L 2924/2076

(57) ABSTRACT

A semiconductor device includes a semiconductor chip in a rectangular shape having longer sides extending in a first direction and shorter sides extending in a second direction. The semiconductor chip includes: a first vertical MOS transistor that includes a first gate pad and a plurality of first source pads, and a second vertical MOS transistor that includes a second gate pad and a plurality of second source pads. A plurality of first linear disposition regions in each of which source pads are linearly aligned in the first direction and a plurality of second linear disposition regions in each of which source pads are linearly aligned in the second direction are provided on an upper surface of the semiconductor chip. The semiconductor device further includes a plurality of ball-shaped bump electrodes connected to the first gate pad, the first source pads, the second gate pad, and the second source pads.

### CROSS REFERENCE TO RELATED APPLICATIONS

This is a continuation application of PCT International Application No. PCT/JP2023/045572 filed on Dec. 19, 2023, designating the United States of America, which is based on and claims priority of U.S. Provisional Patent Application No. 63/491,332 filed on Mar. 21, 2023. The entire disclosures of the above-identified applications, including the specifications, drawings and claims are incorporated herein by reference in their entirety.

### FIELD

The present disclosure relates to a semiconductor device.

### BACKGROUND

Conventionally, semiconductor devices have been known (for example, refer to Patent Literature (PTL) 1.

### CITATION LIST

### Patent Literature

PTL 1: Japanese Unexamined Patent Application Publication No. 2021-005732

### SUMMARY

### Technical Problem

Recently, there are an increasing number of cases in which a semiconductor chip is mounted on a mounting substrate and an underfill material fills a space between the semiconductor chip and the mounting substrate.

In view of this, an object of the present disclosure is to provide a semiconductor device that includes a semiconductor chip and is suitable for filling a space between the semiconductor chip and a mounting substrate with an underfill material after mounting the semiconductor device on the mounting substrate.

### Solution to Problem

A semiconductor device according to an aspect of the present disclosure is a semiconductor device that is a facedown mountable, chip-size-package type semiconductor device, the semiconductor device including: a semiconductor chip in a rectangular shape having longer sides extending in a first direction and shorter sides extending in a second direction in a plan view of the semiconductor device. The semiconductor chip includes: a semiconductor layer that includes a semiconductor substrate; and a first vertical metal-oxide semiconductor (MOS) transistor provided in the semiconductor layer in a first region and a second vertical MOS transistor provided in the semiconductor layer in a second region, the first region being one of two halves of an area of the semiconductor chip in the plan view, the second region being the other one of the two halves. The semiconductor substrate functions as a common drain region of the first vertical MOS transistor and the second vertical MOS transistor. A boundary line between the first region and the second region is a line segment extending in the second direction. The first vertical MOS transistor includes a first gate pad and a plurality of first source pads in the first region in an upper surface of the semiconductor chip. The second vertical MOS transistor includes a second gate pad and a plurality of second source pads in the second region in the upper surface of the semiconductor chip. In the plan view, the first gate pad, the plurality of first source pads, the second gate pad, and the plurality of second source pads are each in a circular shape having a diameter less than 378 [μm]. A plurality of first linear disposition regions and a plurality of second linear disposition regions are disposed on the upper surface of the semiconductor chip in the plan view, the plurality of first linear disposition regions each being a region in which, among the plurality of first source pads and the plurality of second source pads, at least four and at most 2nx source pads are disposed with centers thereof linearly aligned in the first direction, the plurality of second linear disposition regions each being a region in which, among the plurality of first source pads or the plurality of second source pads, at least two and at most ny source pads are disposed with centers thereof linearly aligned in the second direction. In the plan view, a width of each of the plurality of first linear disposition regions is identical to a greatest diameter among diameters of the at least four and at most 2nx source pads disposed in the first linear disposition region, and a width of each of the plurality of second linear disposition regions is identical to a greatest diameter among diameters of the at least two and at most ny source pads disposed in the second linear disposition region. When in the plan view, a length of the longer sides is Lx [μm], a length of the shorter sides is Ly [μm], and a greatest diameter among diameters of the plurality of first source pads and the plurality of second source pads is rs [μm], nx is a greatest integer that is at least 2 and satisfies nx<1/3×(Lx/rs−3), ny is a greatest integer that is at least 2 and satisfies ny<2/3×(Ly/rs−1), and in the plan view, a nearest-neighbor distance of the plurality of first source pads, a nearest-neighbor distance of the plurality of second source pads, and a nearest-neighbor distance of the plurality of second linear disposition regions are each at least rs/2 [μm], and a diameter of the first gate pad and a diameter of the second gate pad are each rs [μm]. In the plan view, the first gate pad is disposed farther from the boundary line than a second linear disposition region in the first region closest to the boundary line is, among the plurality of second linear disposition regions. In the plan view, the second gate pad is disposed farther from the boundary line than a second linear disposition region in the second region closest to the boundary line is, among the plurality of second linear disposition regions. The semiconductor device further includes a plurality of ball-shaped bump electrodes that are connected to at positions directly above and in one-to-one contact with the first gate pad, the plurality of first source pads, the second gate pad, and the plurality of second source pads.

### Advantageous Effects

According to a semiconductor device according to an aspect of the present disclosure, a semiconductor device that is suitable for filling a space between a semiconductor chip and a mounting substrate with an underfill material after the semiconductor device is mounted on the mounting substrate is provided.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a perspective view illustrating an example of a structure of a semiconductor device according to an embodiment.

FIG. 2 is a cross-sectional view schematically illustrating an example of a state in which the semiconductor device according to the embodiment is mounted on a mounting substrate according to the embodiment.

FIG. 3 is a plan view illustrating an example of a structure of the semiconductor device according to the embodiment.

FIG. 4 is a cross-sectional view illustrating an example of a structure of the semiconductor device according to the embodiment.

FIG. 5 is a plan view of a typical example of a semiconductor chip according to the embodiment.

FIG. 6 is a schematic diagram illustrating a relation between diameters of pads according to the embodiment and heights of ball-shaped bump electrodes according to the embodiment after a heating process.

FIG. 7A is a plan view illustrating an example of a positional relation between a first gate pad and a plurality of first source pads and an example of a positional relation between a second gate pad and a plurality of second source pads, according to the embodiment.

FIG. 7B is a plan view illustrating an example of a positional relation between the first gate pad and the plurality of first source pads and an example of a positional relation between the second gate pad and the plurality of second source pads, according to the embodiment.

FIG. 8 is a plan view illustrating adjacent-pad longest distances between source pads in second linear disposition regions, according to the embodiment.

FIG. 9A is a cross-sectional view illustrating an example of a cross section of a ball-shaped bump electrode after a heating process, according to the embodiment.

FIG. 9B is a cross-sectional view illustrating an example of a cross section of a ball-shaped bump electrode after a heating process, according to the embodiment.

FIG. 10 is a list showing relations between a diameter of a pad, a height of a ball-shaped bump electrode after a heating process, and a diameter of a ball-shaped bump electrode before the heating process, according to the embodiment.

FIG. 11A is a line graph showing a relation between a diameter of a source pad and the number of source pads that can be disposed in a second linear disposition region, according to the embodiment.

FIG. 11B is a line graph showing a relation between a diameter of a source pad and an occupancy rate of a total area occupied by source pads with respect to the area of the upper surface of the semiconductor chip, according to the embodiment.

FIG. 12 is a plan view illustrating another example of a structure of the semiconductor device according to the embodiment.

FIG. 13 is a plan view illustrating another example of a structure of the semiconductor device according to the embodiment.

FIG. 14 is a plan view illustrating another example of a structure of the semiconductor device according to the embodiment.

### DESCRIPTION OF EMBODIMENTS

### [Circumstances Leading to Aspects of the Present Disclosure]

Conventionally, a semiconductor chip has been known to include vertical metal-oxide-semiconductor (MOS) transistors having a dual configuration and has a drain in common, which are used for the purpose of protection from overcharge and/or overdischarge of a lithium-ion battery.

Relatively high current flows through such a semiconductor chip. For this reason, a reduction in resistance of a current path of current flowing through a semiconductor chip and an improvement in heat dissipation of the semiconductor chip are expected to be achieved.

On the other hand, as described above, recently, there have been an increasing number of cases in which a semiconductor chip is mounted on a mounting substrate and thereafter an underfill material fills a space between the semiconductor chip and the mounting substrate.

In order to appropriately fill the space between a semiconductor chip and a mounting substrate with an underfill material, it is an effective measure to dispose ball-shaped bump electrodes on the mounting surface of the semiconductor chip.

However, if the interval between ball-shaped bump electrodes is increased in order to enhance spreadability of the underfill material, resistance of a current path of current flowing through a semiconductor chip increases and heat dissipation of the semiconductor chip decreases. On the contrary, if the interval between the ball-shaped bump electrodes is narrowed in order to reduce resistance of a current path of current flowing through a semiconductor chip and/or to improve heat dissipation of the semiconductor chip, the spreadability of the underfill material decreases.

In view of this, the inventors have diligently conducted experiments and examinations on a semiconductor device that can enhance spread of an underfill material after mounting a semiconductor chip that includes vertical MOS transistors having a dual configuration and has a drain in common on a mounting substrate, and at the same time can reduce an increase in resistance of a current path of current flowing through the semiconductor chip and can reduce a decrease in heat dissipation of the semiconductor chip.

As a result, the inventors have conceived a semiconductor device according to the present disclosure as described below.

A semiconductor device according to an aspect of the present disclosure is a semiconductor device that is a facedown mountable, chip-size-package type semiconductor device, the semiconductor device including: a semiconductor chip in a rectangular shape having longer sides extending in a first direction and shorter sides extending in a second direction in a plan view of the semiconductor device. The semiconductor chip includes: a semiconductor layer that includes a semiconductor substrate; and a first vertical metal-oxide semiconductor (MOS) transistor provided in the semiconductor layer in a first region and a second vertical MOS transistor provided in the semiconductor layer in a second region, the first region being one of two halves of an area of the semiconductor chip in the plan view, the second region being the other one of the two halves. The semiconductor substrate functions as a common drain region of the first vertical MOS transistor and the second vertical MOS transistor. A boundary line between the first region and the second region is a line segment extending in the second direction. The first vertical MOS transistor includes a first gate pad and a plurality of first source pads in the first region in an upper surface of the semiconductor chip. The second vertical MOS transistor includes a second gate pad and a plurality of second source pads in the second region in the upper surface of the semiconductor chip. In the plan view, the first gate pad, the plurality of first source pads, the second gate pad, and the plurality of second source pads are each in a circular shape having a diameter less than 378 [μm]. A plurality of first linear disposition regions and a plurality of second linear disposition regions are disposed on the upper surface of the semiconductor chip in the plan view, the plurality of first linear disposition regions each being a region in which, among the plurality of first source pads and the plurality of second source pads, at least four and at most 2nx source pads are disposed with centers thereof linearly aligned in the first direction, the plurality of second linear disposition regions each being a region in which, among the plurality of first source pads or the plurality of second source pads, at least two and at most ny source pads are disposed with centers thereof linearly aligned in the second direction. In the plan view, a width of each of the plurality of first linear disposition regions is identical to a greatest diameter among diameters of the at least four and at most 2nx source pads disposed in the first linear disposition region, and a width of each of the plurality of second linear disposition regions is identical to a greatest diameter among diameters of the at least two and at most ny source pads disposed in the second linear disposition region. When in the plan view, a length of the longer sides is Lx [μm], a length of the shorter sides is Ly [μm], and a greatest diameter among diameters of the plurality of first source pads and the plurality of second source pads is rs [μm], nx is a greatest integer that is at least 2 and satisfies nx<1/3×(Lx/rs−3), ny is a greatest integer that is at least 2 and satisfies ny<2/3×(Ly/rs−1), and in the plan view, a nearest-neighbor distance of the plurality of first source pads, a nearest-neighbor distance of the plurality of second source pads, and a nearest-neighbor distance of the plurality of second linear disposition regions are each at least rs/2 [μm], and a diameter of the first gate pad and a diameter of the second gate pad are each rs [μm]. In the plan view, the first gate pad is disposed farther from the boundary line than a second linear disposition region in the first region closest to the boundary line is, among the plurality of second linear disposition regions. In the plan view, the second gate pad is disposed farther from the boundary line than a second linear disposition region in the second region closest to the boundary line is, among the plurality of second linear disposition regions. The semiconductor device further includes a plurality of ball-shaped bump electrodes that are connected to at positions directly above and in one-to-one contact with the first gate pad, the plurality of first source pads, the second gate pad, and the plurality of second source pads.

According to the semiconductor device having the above configuration, in a state in which the semiconductor device is mounted facedown on the mounting substrate, straight spaces extending in the second direction are provided between the semiconductor chip and the mounting substrate. Accordingly, the underfill material can be poured in between the semiconductor chip and the mounting substrate through the straight spaces.

Normally, it is known that when a semiconductor device that includes a semiconductor chip in a rectangular shape is mounted facedown on the mounting substrate by reflow, the semiconductor chip often curves along the first direction that is the longer side direction of the semiconductor chip and in a direction in which a center portion thereof moves away from the mounting substrate, due to the heat during reflow.

In contrast, according to the semiconductor device having the above configuration, the straight spaces that are provided extend in the second direction orthogonal to the first direction. For this reason, for example, even if the semiconductor chip curves along the first direction and in a direction in which a center portion thereof moves away from the mounting substrate when the semiconductor device is mounted on the mounting substrate the underfill material can be poured in between the semiconductor chip and the mounting substrate through the straight spaces extending in the second direction orthogonal to the first direction.

For this reason, according to the semiconductor device having the above configuration, the spread of the underfill material can be enhanced regardless of whether or not the semiconductor chip curves when the semiconductor device is mounted on the mounting substrate.

Furthermore, according to the semiconductor device having the above configuration, a relatively large number of ball-shaped bump electrodes directly above a plurality of first source pads and a plurality of second source pads can be provided.

For this reason, according to the semiconductor device having the above configuration, an increase in resistance of a current path of current flowing through the semiconductor chip can be reduced and a decrease in heat dissipation of the semiconductor chip can be reduced after the semiconductor device is mounted on the mounting substrate.

As described above, according to the semiconductor device having the above configuration, the spread of the underfill material after the semiconductor device is mounted on the mounting substrate can be enhanced, and at the same time, an increase in resistance of a current path of current flowing through the semiconductor chip can be reduced and a decrease in heat dissipation of the semiconductor chip can be reduced.

Thus, according to the semiconductor device having the above configuration, a semiconductor device that is suitable for filling a space between the semiconductor chip and the mounting substrate with an underfill material after the semiconductor device is mounted on the mounting substrate is provided.

A nearest-neighbor distance of the plurality of first linear disposition regions may be at least rs/2 [μm] in the plan view.

Accordingly, in a state in which the semiconductor device is mounted facedown on the mounting substrate, straight spaces extending in the first direction can be further provided between the semiconductor chip and the mounting substrate.

Thus, after the semiconductor device is mounted on the mounting substrate, the spread of the underfill material can be further enhanced.

A diameter of each of the plurality of first source pads and the plurality of second source pads may be rs [μm] in the plan view.

Accordingly, in a state in which the semiconductor device is mounted facedown on the mounting substrate, an increase in resistance of a current path of current flowing through the semiconductor chip can be further reduced, and a decrease in heat dissipation of the semiconductor chip can be further reduced.

In the plan view, among the at least four and at most 2nx source pads in each of the plurality of first linear disposition regions, source pads in the first region may have diameters that exhibit a monotonic decrease from a source pad farthest from the boundary line to a source pad closest to the boundary line, and source pads in the second region may have diameters that exhibit a monotonic decrease from a source pad farthest from the boundary line to a source pad closest to the boundary line.

Normally, when a heating process is performed to bond a ball-shaped bump electrode to a circular pad in a state in which the ball-shaped bump electrode is disposed on the circular pad, a height of the ball-shaped bump electrode, after a heating process, from the surface of the semiconductor chip increases as the diameter of the circular pad decreases.

For this reason, according to the semiconductor device having the above configuration, when the semiconductor device is mounted on the mounting substrate, in the case in which the semiconductor chip curves along the first direction and in a direction in which a center portion thereof moves away from the mounting substrate, if a direction orthogonal to the first direction and the second direction is assumed to be a third direction, positions of the apexes in the third direction of the ball-shaped bump electrodes at positions directly above the source pads in each of the first linear disposition regions can be made relatively uniform.

In the plan view, among the at least four and at most 2nx source pads in each of the plurality of first linear disposition regions, source pads in the first region may have nearest-neighbor distances that exhibit a monotonic increase from a source pad farthest from the boundary line to a source pad closest to the boundary line, and source pads in the second region may have nearest-neighbor distances that exhibit a monotonic increase from a source pad farthest from the boundary line to a source pad closest to the boundary line.

As described above, normally, when a heating process is performed to bond a ball-shaped bump electrode to a circular pad in a state in which the ball-shaped bump electrode is disposed on the circular pad, a height of the ball-shaped bump electrode, after a heating process is performed, from the surface of the semiconductor chip increases as the diameter of the circular pad decreases. When the distances between the centers of circular pads are the same, the nearest-neighbor distances of the circular pads become longer as the diameters of the circular pads are smaller. Stated differently, in this case, the height of a ball-shaped bump electrode from the surface of the semiconductor chip can be said to increase as a nearest-neighbor distance of a pad increases.

For this reason, according to the semiconductor device having the above configuration, when the semiconductor device is mounted on the mounting substrate, in the case in which the semiconductor chip curves along the first direction and in a direction in which a center portion thereof moves away from the mounting substrate, if a direction orthogonal to the first direction and the second direction is assumed to be a third direction, positions of the apexes in the third direction of the ball-shaped bump electrodes at positions directly above the source pads in each of the first linear disposition regions can be made relatively uniform.

In the plan view, in each of second linear disposition regions facing closest to each other across the boundary line among the plurality of second linear disposition regions, the at least two and at most ny source pads may each have a diameter identical to a smallest diameter among diameters of the plurality of first source pads and the plurality of second source pads.

As described above, normally, when a heating process is performed to bond a ball-shaped bump electrode to a circular pad in a state in which the ball-shaped bump electrode is disposed on the circular pad, a height of the ball-shaped bump electrode, after a heating process is performed, from the surface of the semiconductor chip increases as the diameter of the circular pad decreases.

For this reason, according to the semiconductor device having the above configuration, when the semiconductor device is mounted on the mounting substrate, in the case in which the semiconductor chip curves along the first direction and in a direction in which a center portion thereof moves away from the mounting substrate, if a direction orthogonal to the first direction and the second direction is assumed to be a third direction, positions of the apexes in the third direction of the ball-shaped bump electrodes at positions directly above the source pads in each of the first linear disposition regions can be made relatively uniform.

In the plan view, among the plurality of ball-shaped bump electrodes, ball-shaped bump electrodes positioned directly above the at least four and at most 2nx source pads disposed in each of the plurality of first linear disposition regions include: ball-shaped bump electrodes in the first region, heights of which from the upper surface of the semiconductor chip may exhibit a monotonic increase from a ball-shaped bump electrode farthest from the boundary line to a ball-shaped bump electrode closest to the boundary line; and ball-shaped bump electrodes in the second region, heights of which from the upper surface of the semiconductor chip may exhibit a monotonic increase from a ball-shaped bump electrode farthest from the boundary line to a ball-shaped bump electrode closest to the boundary line.

Accordingly, when the semiconductor device is mounted on the mounting substrate, in the case in which the semiconductor chip curves along the first direction and in a direction in which a center portion thereof moves away from the mounting substrate, if a direction orthogonal to the first direction and the second direction is assumed to be a third direction, positions of the apexes in the third direction of the ball-shaped bump electrodes at positions directly above the source pads in each of the first linear disposition regions can be made relatively uniform.

In the plan view, among the plurality of ball-shaped bump electrodes, ball-shaped bump electrodes positioned directly above the at least four and at most 2nx source pads disposed in each of the plurality of first linear disposition regions include: ball-shaped bump electrodes in the first region, surface areas of which may exhibit a monotonic increase from a ball-shaped bump electrode farthest from the boundary line to a ball-shaped bump electrode closest to the boundary line; and ball-shaped bump electrodes in the second region, surface areas of which may exhibit a monotonic increase from a ball-shaped bump electrode farthest from the boundary line to a ball-shaped bump electrode closest to the boundary line.

As described above, normally, when a heating process is performed to bond a ball-shaped bump electrode to a circular pad in a state in which the ball-shaped bump electrode is disposed on the circular pad, a height of the ball-shaped bump electrode, after a heating process is performed, from the surface of the semiconductor chip increases as the diameter of the circular pad decreases. Normally, the higher the height of a ball-shaped bump electrode from the surface of the semiconductor chip is, the more the surface area of the ball-shaped bump electrode increases. Stated differently, it can be said that the greater the surface area of a ball-shaped bump electrode is, the higher the height thereof from the surface of the semiconductor chip is.

For this reason, according to the semiconductor device having the above configuration, when the semiconductor device is mounted on the mounting substrate, in the case in which the semiconductor chip curves along the first direction and in a direction in which a center portion thereof moves away from the mounting substrate, if a direction orthogonal to the first direction and the second direction is assumed to be a third direction, positions of the apexes in the third direction of the ball-shaped bump electrodes at positions directly above the source pads in each of the first linear disposition regions can be made relatively uniform.

In the plan view, a total number of the at least two and at most ny source pads disposed in each of second linear disposition regions facing closest to each other across the boundary line among the plurality of second linear disposition regions may be ny.

In the semiconductor device having the above configuration, among the current paths of current flowing through the semiconductor chip, a current path of current flowing through the semiconductor chip via source pads disposed in second linear disposition regions facing closest to each other across the boundary line among the plurality of second linear disposition regions is the shortest inside the semiconductor chip.

For this reason, as with the above configuration by setting the number of source pads disposed in, among the plurality of second linear disposition regions, the second linear disposition regions facing closest to each other across the boundary line to ny that is the greatest number of at least two and at most ny, an increase in resistance of a current path of current flowing through the semiconductor chip can be reduced after mounting the semiconductor device on the mounting substrate.

In the plan view, a distance between the first gate pad and a first source pad closest to the first gate pad among the plurality of first source pads may be at least rs [μm] and may be longer than the nearest-neighbor distance of the plurality of first source pads, and a distance between the second gate pad and a second source pad closest to the second gate pad among the plurality of second source pads may be at least rs [μm] and may be longer than the nearest-neighbor distance of the plurality of second source pads.

Accordingly, a short circuit between the first gate pad and any of the plurality of first source pads and a short circuit between the second gate pad and any of the plurality of second source pads can be prevented.

In the plan view, an adjacent-pad longest distance that is a longest distance among distances between pairs of adjacent source pads included in the at least two and at most ny source pads in each of the plurality of second linear disposition regions may monotonically decrease in the first region from a second linear disposition region farthest from the boundary line to a second linear disposition region closest to the boundary line among the plurality of second linear disposition regions, and may monotonically decrease in the second region from a second linear disposition region farthest from the boundary line to a second linear disposition region closest to the boundary line among the plurality of second linear disposition regions, and a total number of the at least four and at most 2nx source pads in each of the plurality of first linear disposition regions (1) may monotonically decrease in, among the plurality of first linear disposition regions, two or more first linear disposition regions spaced apart from one longer side out of the longer sides by a distance shorter than a distance to the other longer side out of the longer sides from a first linear disposition region closest to the one longer side to a first linear disposition region farthest from the one longer side, and (2) may monotonically decrease in, among the plurality of first linear disposition regions, two or more first linear disposition regions spaced apart from the other longer side by a distance shorter than a distance to the one longer side from a first linear disposition region closest to the other longer side to a first linear disposition region farthest from the other longer side.

In the plan view, among the plurality of first linear disposition regions, positions of the at least four and at most 2nx source pads in the second direction in one first linear disposition region included in adjacent first linear disposition regions may not coincide with positions of the at least four and at most 2nx source pads in the second direction in another first linear disposition region included in the adjacent first linear disposition regions.

Also, rs may be at least 196 and at most 226 or at least 250 and at most 280.

In the plan view, among the at least four and at most 2nx source pads disposed in each of the plurality of first linear disposition regions, a diameter of a source pad in the first region farthest from the boundary line and a diameter of a source pad in the second region farthest from the boundary line may be at least 250 [μm] and at most 280 [μm], and a diameter of a source pad in the first region closest to the boundary line and a diameter of a source pad in the second region closest to the boundary line may be at least 196 [μm] and at most 226 [μm].

Also, rs may be greater than 150, a height of each of the plurality of ball-shaped bump electrodes from the upper surface of the semiconductor chip may be at least 70 [μm] and at most 130 [μm], and a cross-sectional area of each of the plurality of ball-shaped bump electrodes along a plane parallel to the upper surface of the semiconductor chip may monotonically decrease from a portion of the ball-shaped bump electrode close to the upper surface of the semiconductor chip to a portion of the ball-shaped bump electrode far from the upper surface of the semiconductor chip.

In the following, a specific example of a semiconductor device according to an aspect of the present disclosure is to be described with reference to the drawings. The embodiments shown herein are specific examples of the present disclosure. Thus, numerical values, shapes, elements, arrangement and connection of the elements, steps (processes), and the processing order of the steps described in the embodiments below are examples, and are not intended to limit the present disclosure. The drawings are schematic diagrams, and do not necessarily provide strictly accurate illustration. In the drawings, the same reference sign is given to a substantially same configuration, and a redundant description thereof is omitted or simplified.

In the present disclosure, a distance between a first element and a second element refers to the shortest distance among the distances each between a point on the outer periphery of the first element and a point on the outer periphery of the second element.

In the present disclosure, a nearest-neighbor distance of a plurality of elements refers to a shortest distance among the distances between all combinations of two elements among the plurality of elements.

In the present disclosure, a monotonic change means to be a monotonically increasing function in a broad sense or a monotonically decreasing function in a broad sense. Stated differently, the monotonically increasing function in a broad sense refers to function f(x) with which f(x1)≤f(x2) when x1<x2, whereas the monotonically decreasing function in a broad sense refers to function f(x) with which f(x1)≥f(x2) when x1<x2.

### EMBODIMENTS

### <Structure of Semiconductor Device>

In the following, a structure of a semiconductor device according to an embodiment is to be described. The semiconductor device according to the embodiment includes a semiconductor chip having a dual configuration and including two vertical metal oxide semiconductor (MOS) transistors that share a drain, and a plurality of ball-shaped bump electrodes. The two vertical MOS transistors are, for example, so-called trench MOS transistors. Here, a description is given assuming that the two vertical MOS transistors are so-called trench MOS transistors.

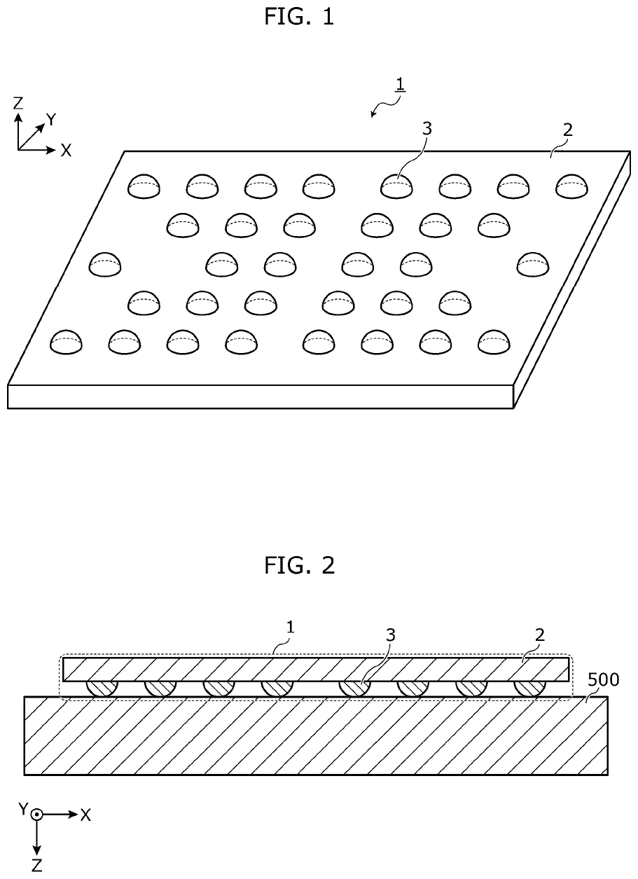

FIG. 1 is a perspective view illustrating an example of a structure of semiconductor device 1 according to the embodiment. As illustrated in FIG. 1, semiconductor device 1 includes semiconductor chip 2 and plural ball-shaped bump electrodes 3 disposed on an upper surface of semiconductor chip 2.

More specifically, semiconductor device 1 includes, on the upper surface of semiconductor chip 2, plural ball-shaped bump electrodes 3 that are connected or stated differently, bonded to at positions directly above and in one-to-one contact with later-described first gate pad 119, later-described plural first source pads 111, later-described second gate pad 129, and later-described plural second source pads 121.

Plural ball-shaped bump electrodes 3 are provided, for example, by performing a heating process on a solder ball material.

FIG. 2 is a cross-sectional view schematically illustrating an example of a state in which semiconductor device 1 is mounted on mounting substrate 500. As illustrated in FIG. 2, semiconductor device 1 is mounted facedown on mounting substrate 500.

As illustrated in FIG. 2, since semiconductor device 1 includes plural ball-shaped bump electrodes 3 on the upper surface of semiconductor chip 2, a space is provided between semiconductor chip 2 and mounting substrate 500 in a state in which semiconductor device 1 is mounted on mounting substrate 500. For this reason, an underfill material can be spread between semiconductor chip 2 and mounting substrate 500 in a state in which semiconductor device 1 is mounted on mounting substrate 500.

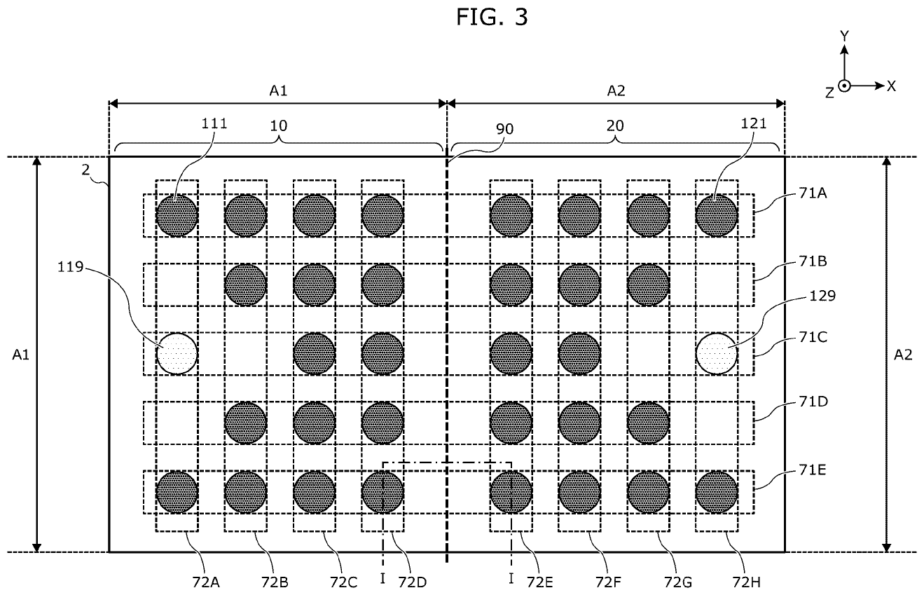

FIG. 3 is a plan view illustrating an example of a structure of semiconductor device 1. Note that FIG. 3 is a drawing from which illustration of plural ball-shaped bump electrodes 3 is omitted. For this reason, FIG. 3 is also a plan view of semiconductor chip 2.

As illustrated in FIG. 3, in the plan view of semiconductor device 1 or stated differently, in the plan view of semiconductor chip 2, semiconductor chip 2 is in a rectangular shape having longer sides extending in a first direction (the X-axis direction in FIG. 3) and shorter sides extending in a second direction (the Y-axis direction in FIG. 3).

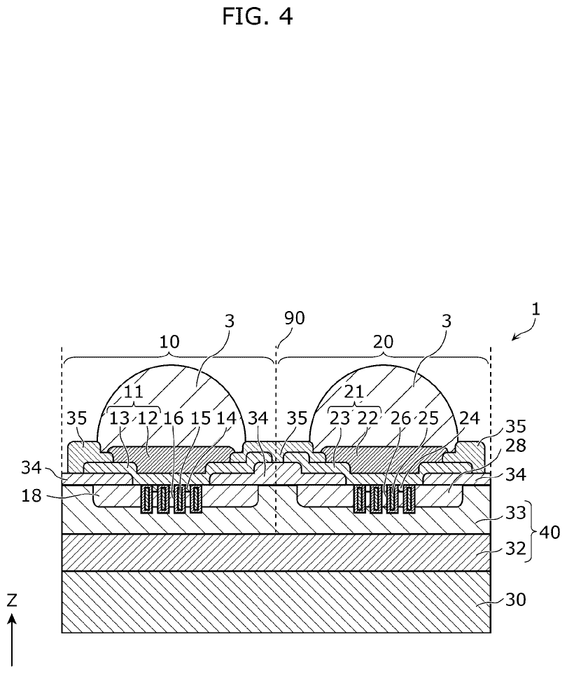

FIG. 4 is a cross-sectional view illustrating an example of a structure of semiconductor device 1. FIG. 4 illustrates a cut surface taken along I-I in FIG. 3.

As illustrated in FIG. 3 and FIG. 4, semiconductor chip 2 includes metal layer 30, semiconductor layer 40, oxide film 34, protective film 35, first vertical MOS transistor 10 provided in semiconductor layer 40 in first region A1 that is one of two halves of the area of semiconductor chip 2 in the plan view of semiconductor chip 2, and second vertical MOS transistor 20 provided in semiconductor layer 40 in second region A2 that is the other one of the two halves.

Here, in the plan view of semiconductor device 1, boundary line 90 between first region A1 and second region A2 is a line segment extending in the second direction (the Y-axis direction in FIG. 3).

Boundary line 90 can be considered as a virtual line that follows a center position of the interval between portion 13 of first source electrode 11 and portion 23 of second source electrode 21. Although the width of the interval is finite, the interval itself can be considered as boundary line 90. Even in the case of the interval, the appearance of the interval seen with the naked eye or at a low magnification can be recognized as a line.

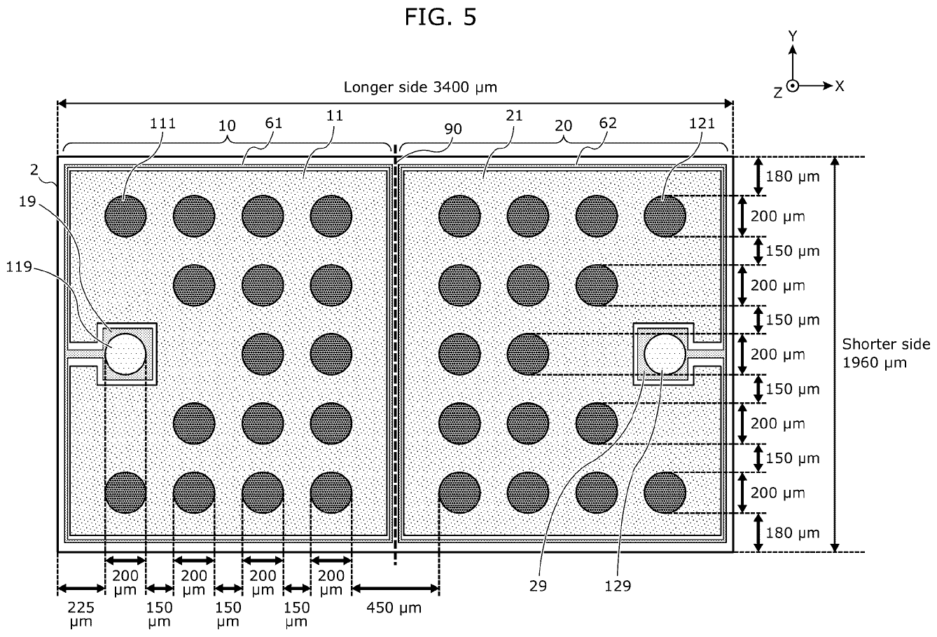

Here, first vertical MOS transistor 10 includes, in first region A1, first source electrode 11 and first gate electrode 19 (illustrated in FIG. 5 described later) that is not illustrated in FIG. 3 or FIG. 4, whereas second vertical MOS transistor 20 includes, in second region A2, second source electrode 21 and second gate electrode 29 (illustrated in FIG. 5 described later) that is not illustrated in FIG. 3 or FIG. 4.

Here, first vertical MOS transistor 10 includes first gate pad 119 and plural first source pads 111 in the upper surface of semiconductor chip 2 in first region A1, whereas second vertical MOS transistor 20 includes second gate pad 129 and plural second source pads 121 in the upper surface of semiconductor chip 2 in second region A2.

Here, in the plan view of semiconductor device 1, first gate pad 119, plural first source pads 111, second gate pad 129, and plural second source pads 121 are each in a circular shape having a diameter less than 378 [μm].

In the present disclosure, a description is given assuming that semiconductor chip 2 includes metal layer 30, yet a configuration of semiconductor chip 2 is not necessarily limited to a configuration that includes metal layer 30.

Semiconductor layer 40 is configured as a stack of semiconductor substrate 32 and low-concentration impurity layer 33.

Semiconductor substrate 32 is provided on the lower surface side of semiconductor layer 40, and is made of silicon that includes impurities of a first conductivity type.

Low-concentration impurity layer 33 is disposed on the upper surface side of semiconductor layer 40, provided in contact with semiconductor substrate 32, and includes impurities of the first conductivity type having a concentration lower than the concentration of impurities of the first conductivity type of semiconductor substrate 32. Low-concentration impurity layer 33 may be provided on semiconductor substrate 32 by epitaxial growth, for example.

Oxide film 34 is disposed on the upper surface of semiconductor layer 40, and is provided in contact with low-concentration impurity layer 33.

Protective film 35 covers the upper surface of first vertical MOS transistor 10 and the upper surface of second vertical MOS transistor 20, and includes a plurality of opening portions.

Here, protective film 35 covering the upper surface of first vertical MOS transistor 10 and the upper surface of second vertical MOS transistor 20 refers to a state in which protective film 35 is provided on substantially the entire surface of semiconductor chip 2 except the opening portions in the plan view of semiconductor layer 40. Here, substantially the entire surface of semiconductor chip 2 refers to the entire surface of semiconductor chip 2 except the perimeter region that is slightly left along the four sides of semiconductor chip 2 after being diced, out of the wafer region allocated as a dicing margin for when semiconductor chip 2 is cut out from the wafer by being diced. For this reason, oxide film 34 is exposed from the upper surface of semiconductor chip 2, exceptionally in the perimeter region.

The opening portions of protective film 35 in the present disclosure each refer to a shape where entire perimeter of the opening portion is closed with protective film 35 in the plan view of semiconductor device 1. For this reason, in the plan view of semiconductor device 1, a shape where a portion of the perimeter of an opening portion overlaps the perimeter region where oxide film 34 is exceptionally exposed from the upper surface of semiconductor chip 2 as stated above does not correspond to an opening portion of protective film 35 in the present disclosure.

Metal layer 30 is provided in contact with the lower surface of semiconductor substrate 32, may comprise silver, copper, nickel, or an alloy of such metals, or may comprise a metal material having a conductivity high enough to allow metal layer 30 to function as an electrode. Note that metal layer 30 may include a trace amount of an element other than metal, which is mixed as an impurity in a process of manufacturing the metal material.

First body region 18 that includes impurities of a second conductivity type different from the first conductivity type is provided in low-concentration impurity layer 33 in first region A1. First gate conductor 15, first gate insulating film 16, and first source region 14 that includes impurities of the first conductivity type are provided in first body region 18.

First source electrode 11 includes portion 12 and portion 13, and portion 12 is connected to first source region 14 and first body region 18 via portion 13.

First gate conductor 15 is electrically connected to first gate electrode 19 not illustrated in FIG. 3 or FIG. 4 (but illustrated in FIG. 5 described later) via first gate wiring 61 not illustrated in FIG. 3 or FIG. 4 (but illustrated in FIG. 5 described later).

Portion 12 is a layer in contact with and connected to ball-shaped bump electrodes 3, or stated differently, is a layer bonded to ball-shaped bump electrodes 3, and may comprise, as a non-limiting example, a metal material including at least one of nickel, titanium, tungsten, or palladium. The upper surface of portion 12 may be plated with gold, for instance.

The upper surface of portion 12 includes a plurality of exposed portions that are exposed from the upper surface of semiconductor chip 2 via the plurality of opening portions of protective film 35. The plurality of exposed portions correspond to plural first source pads 111. Stated differently, plural first source pads 111 correspond to the plurality of exposed portions of portion 12.

Portion 13 is a layer that connects portion 12 to first source region 14 and first body region 18, and may comprise, as a non-limiting example, a metal material including at least one of aluminum, copper, gold, or silver.

An upper surface of first gate electrode 19 not illustrated in FIG. 3 or FIG. 4 (but illustrated in FIG. 5 described later) includes an exposed portion that is exposed from the upper surface of semiconductor chip 2 via an opening portion of protective film 35.

The exposed portion corresponds to first gate pad 119. Stated differently, first gate pad 119 is an exposed portion of first gate electrode 19 not illustrated in FIG. 3 or FIG. 4 (but illustrated in FIG. 5 described later).

Second body region 28 that includes impurities of the second conductivity type different from the first conductivity type is provided in low-concentration impurity layer 33 in second region A2. Second source region 24 that includes impurities of the first conductivity type, second gate conductor 25, and second gate insulating film 26 are provided in second body region 28.

Second source electrode 21 includes portion 22 and portion 23, and portion 22 is connected to second source region 24 and second body region 28 via portion 23.

Second gate conductor 25 is electrically connected to second gate electrode 29 not illustrated in FIG. 3 or FIG. 4 (but illustrated in FIG. 5 described later) via second gate wiring 62 not illustrated in FIG. 3 or FIG. 4 (but illustrated in FIG. 5 described later).

Portion 22 is a layer in contact with and connected to ball-shaped bump electrodes 3, or stated differently, is a layer bonded to ball-shaped bump electrodes 3, and may comprise, as a non-limiting example, a metal material including at least one of nickel, titanium, tungsten, or palladium. The upper surface of portion 22 may be plated with gold, for instance.

The upper surface of portion 22 includes a plurality of exposed portions that are exposed from the upper surface of semiconductor chip 2 via the plurality of opening portions of protective film 35. The plurality of exposed portions correspond to plural second source pads 121. Stated differently, plural second source pads 121 correspond to the plurality of exposed portions of portion 22.

Portion 23 is a layer that connects portion 22 to second source region 24 and second body region 28, and may comprise, as a non-limiting example, a metal material including at least one of aluminum, copper, gold, or silver.

An upper surface of second gate electrode 29 not illustrated in FIG. 3 or FIG. 4 (but illustrated in FIG. 5 described later) includes an exposed portion that is exposed from the upper surface of semiconductor chip 2 via an opening portion of protective film 35. The exposed portion corresponds to second gate pad 129. Stated differently, second gate pad 129 is an exposed portion of second gate electrode 29 not illustrated in FIG. 3 or FIG. 4 (but illustrated in FIG. 5 described later).

According to the above configurations of first vertical MOS transistor 10 and second vertical MOS transistor 20, a portion of low-concentration impurity layer 33 and semiconductor substrate 32 function as a common drain region having a first drain region of first vertical MOS transistor 10 and a second drain region of second vertical MOS transistor 20 in common. Stated differently, semiconductor substrate 32 functions as a common drain region for first vertical MOS transistor 10 and second vertical MOS transistor 20.

In semiconductor chip 2, for example, assuming that the first conductivity type is an N type and the second conductivity type is a P type, first source region 14, second source region 24, semiconductor substrate 32, and low-concentration impurity layer 33 may be N-type semiconductors, and first body region 18 and second body region 28 may be P-type semiconductors.

In semiconductor chip 2, for example, assuming that the first conductivity type is a P type and the second conductivity type is an N type, first source region 14, second source region 24, semiconductor substrate 32, and low-concentration impurity layer 33 may be P-type semiconductors, and first body region 18 and second body region 28 may be N-type semiconductors.

In the present disclosure, a description is given assuming that first vertical MOS transistor 10 and second vertical MOS transistor 20 are N channel transistors with the first conductivity type being an N type and the second conductivity type being a P type.

Furthermore, in the present disclosure, a description is given assuming that first vertical MOS transistor 10 and second vertical MOS transistor 20 are similar to each other. Moreover, in the present disclosure, a description is given assuming that the structure of first vertical MOS transistor 10 and the structure of second vertical MOS transistor 20 are in an axisymmetric relation with boundary line 90 as an axis of symmetry in the plan view of semiconductor device 1.

As illustrated in FIG. 3, plural first linear disposition regions 71 (corresponding to first linear disposition region 71A to first linear disposition region 71E in FIG. 3) and plural second linear disposition regions 72 (corresponding to second linear disposition region 72A to second linear disposition region 72H in FIG. 3) are disposed on the upper surface of semiconductor chip 2 in the plan view of semiconductor device 1, plural first linear disposition regions 71 each being a region in which, among plural first source pads 111 and plural second source pads 121, at least four and at most 2nx (the definition of nx is to be later stated, and nx is 4 in the example illustrated in FIG. 3) source pads are disposed with centers thereof linearly aligned in the first direction, plural second linear disposition regions 72 each being a region in which, among plural first source pads 111 or plural second source pads 121, at least two and at most ny (the definition of ny is to be later stated, and ny is 4 in the example illustrated in FIG. 3) source pads are disposed with centers thereof linearly aligned in the second direction.

Here, in the plan view of semiconductor device 1, a width of each of plural first linear disposition regions 71 is identical to a greatest diameter among diameters of the source pads disposed in first linear disposition region 71, and a width of each of plural second linear disposition regions 72 is identical to a greatest diameter among diameters of the source pads disposed in second linear disposition region 72.

Here, in the plan view of semiconductor device 1, when a length of the longer sides of semiconductor chip 2 is denoted by Lx [μm], a length of the shorter sides is denoted by Ly [μm], and a greatest diameter among diameters of plural first source pads 111 and plural second source pads 121 is denoted by rs [μm], nx is a greatest integer that is at least 2 and satisfies nx<1/3×(Lx/rs−3), and ny is a greatest integer that is at least 2 and satisfies ny<2/3×(Ly/rs−1).

Here, in the plan view of semiconductor device 1, a nearest-neighbor distance of plural first source pads 111, a nearest-neighbor distance of plural second source pads 121, and a nearest-neighbor distance of plural second linear disposition regions 72 are each at least rs/2 [μm], and a diameter of first gate pad 119 and a diameter of second gate pad 129 are each rs [μm].

Here, in the plan view of semiconductor device 1, first gate pad 119 is disposed farther from boundary line 90 than second linear disposition region 72 in first region A1 closest to boundary line 90 is from boundary line 90, and second gate pad 129 is disposed farther from boundary line 90 than second linear disposition region 72 in second region A2 closest to boundary line 90 is from boundary line 90.

### <Typical Example of Semiconductor Chip>

In the following, a typical example of semiconductor chip 2 is to be described.

FIG. 5 is a plan view of a typical example of semiconductor chip 2. In FIG. 5, first source electrode 11, first gate electrode 19, first gate wiring 61, second source electrode 21, second gate electrode 29, and second gate wiring 62 are illustrated as if the elements were viewable from the outside of semiconductor chip 2, but these elements cannot be directly viewed from the outside of semiconductor chip 2.

As illustrated in FIG. 5, in the plan view pf semiconductor device 1, typically, the diameter of all the pads in semiconductor chip 2 may be the same and 200 [μm]. Here, the pads refer to first gate pad 119, plural first source pads 111, second gate pad 129, and plural second source pads 121.

Typically, in the plan view of semiconductor device 1, semiconductor chip 2 may have longer sides of 3400 [μm] and shorter sides of 1960 [μm].

Semiconductor chip 2 may typically include five first linear disposition regions 71 and eight second linear disposition regions 72.

In a typical example, all the source pads in semiconductor chip 2 may be disposed in one of plural first linear disposition regions 71 and one of plural second linear disposition regions 72. Here, the source pads refer to plural first source pads 111 and plural second source pads 121.

In a typical example, in semiconductor chip 2, the number of source pads disposed in each first linear disposition region 71 may be at least four and at most eight, and the number of source pads disposed in each second linear disposition region 72 may be at least two and at most five.

Typically, in the plan view of semiconductor device 1, in semiconductor chip 2, the nearest-neighbor distance of plural first linear disposition regions 71 may be 150 [μm], and the nearest-neighbor distance of plural second linear disposition regions 72 may be 150 [μm].

### <Consideration>

In the following, a structure of semiconductor chip 2 having the above configuration is to be considered with reference to FIG. 2 to FIG. 4.

Ball-shaped bump electrode 3 may protrude from an outer periphery of a pad by a protrusion amount that is a maximum of a quarter of the diameter of the pad in the plan view of semiconductor device 1, during a heating process of bonding ball-shaped bump electrode 3 to the pad and/or when ball-shaped bump electrode 3 is mounted onto the mounting substrate. For this reason, in order to avoid contact between ball-shaped bump electrodes 3 positioned directly above adjacent pads even when a heating process is performed on ball-shaped bump electrodes 3, the positions at which the pads are disposed are to be determined, considering such a protrusion amount.

In the following, a description is given assuming that all the source pads have the same diameter, or stated differently, the maximum diameter of rs [μm], in order to avoid making the description unnecessarily complicated.

In order to avoid contact between ball-shaped bump electrodes 3 positioned directly above two source pads adjacent to each other even when ball-shaped bump electrodes 3 protrude by the protrusion amount of rs/4 [μm], a distance between the adjacent source pads may be at least (rs/4)×2=rs/2 [μm].

If ball-shaped bump electrodes 3 positioned directly above pads adjacent to each other are not in contact, the spread of the underfill material will not be interrupted.

In particular, since a distance between second linear disposition regions 72 adjacent to each other is rs/2 [μm], straight spaces extending in the second direction are provided between semiconductor chip 2 and mounting substrate 500. Accordingly, the underfill material can be poured in between semiconductor chip 2 and mounting substrate 500 through these straight spaces.

A distance between a longer side of semiconductor chip 2 and ball-shaped bump electrode 3 may be at least rs/2 [μm] in order to prevent ball-shaped bump electrode 3 from flowing outside of semiconductor chip 2 in the second direction. Furthermore, as described above, ball-shaped bump electrode 3 may protrude from an outer periphery of a pad by a protrusion amount that is a maximum of a quarter of the diameter of the pad in the plan view of semiconductor device 1, during a heating process of bonding ball-shaped bump electrode 3 to the pad and/or when ball-shaped bump electrode 3 is mounted onto the mounting substrate. Thus, a distance between the longer side of semiconductor chip 2 and a source pad positioned in the vicinity of the longer side may be at least rs/2+rs/4=rs×3/4 [μm].

The above shows that ny denoting the maximum number of source pads that can be disposed in each second linear disposition region 72 may be the greatest integer with which Ly−ny×rs≥(rs/2)×(ny−1)+rs×(3/4)×2 is satisfied.

Thus, it shows that ny may be the greatest integer that satisfies ny<2/3×(Ly/rs−1).

It is known that when semiconductor device 1 that includes semiconductor chip 2 in a rectangular shape is to be mounted facedown onto mounting substrate 500 by reflow, semiconductor chip 2 may curve along the first direction that is the longer side direction of semiconductor chip 2 and in a direction in which a center portion of semiconductor chip 2 moves away from mounting substrate 500.

For this reason, a distance between a shorter side of semiconductor chip 2 and ball-shaped bump electrode 3 may be at least rs×3/4 [μm] in order to prevent ball-shaped bump electrode 3 from flowing outside of semiconductor chip 2 in the first direction.

In the center portion of semiconductor chip 2, a distance between boundary line 90 and ball-shaped bump electrode 3 may be at least rs×3/4 [μm], in order to prevent a short circuit between first vertical MOS transistor 10 and second vertical MOS transistor 20.

Furthermore, as described above, ball-shaped bump electrode 3 may protrude from an outer periphery of a pad by a maximum of a quarter of the diameter of the pad in the plan view of semiconductor device 1, during a heating process of bonding ball-shaped bump electrode 3 to the pad and/or when ball-shaped bump electrode 3 is mounted onto the mounting substrate. Thus, a distance between a shorter side of semiconductor chip 2 and a source pad positioned in the vicinity of the shorter side may be at least rs×3/4+rs/4=rs [μm].

Similarly, a distance between boundary line 90 and a source pad positioned in the vicinity of boundary line 90 may be at least rs×3/4+rs/4=rs [μm].

The above shows that in first linear disposition regions 71, when only the range for first vertical MOS transistor 10 is viewed, assuming that nx denotes the maximum number of source pads that can be disposed, nx may be the greatest integer with which Lx/2−nx×rs≥(rs/2)×(nx−1)+rs×2 is satisfied.

Since the maximum number of source pads that can be disposed in each first linear disposition region 71 is twice the number of nx, it shows that the number of source pads may be twice nx that denotes the greatest integer that satisfies nx<1/3×(Lx/rs−3).

In the plan view of semiconductor device 1, a region between two second linear disposition regions 72 facing closest to each other across boundary line 90 is a facing region in which first vertical MOS transistor 10 and second vertical MOS transistor 20 face each other and is a region in which a current density is the highest on a current path of current flowing through semiconductor chip 2.

For this reason, in the facing region, disposing elements that can be factors of obstructing a current flow should be avoided as much as possible.

Thus, in the plan view of semiconductor device 1, first gate pad 119 may be disposed farther from boundary line 90 than second linear disposition region 72 in first region A1 closest to boundary line 90 is from boundary line 90, and second gate pad 129 may be disposed farther from boundary line 90 than second linear disposition region 72 in second region A2 closest to boundary line 90 is from boundary line 90.

According to semiconductor device 1 having the above configuration, in a state in which semiconductor device 1 is mounted facedown on mounting substrate 500, straight spaces extending in the second direction are provided between semiconductor chip 2 and mounting substrate 500. Accordingly, the underfill material can be poured in between semiconductor chip 2 and mounting substrate 500 through these straight spaces.

Normally, it is known that when semiconductor device 1 that includes semiconductor chip 2 in a rectangular shape in the plan view of semiconductor device 1 is to be mounted facedown onto mounting substrate 500 by reflow, semiconductor chip 2 may curve along the first direction (the X-axis direction in FIG. 3) that is the longer side direction of semiconductor chip 2, and in a direction in which a center portion of semiconductor chip 2 moves away from mounting substrate 500 due to the heat during reflow.

In contrast, according to semiconductor device 1 having the above configuration, provided straight spaces extend in the second direction (the Y-axis direction in FIG. 3) orthogonal to the first direction. For this reason, for example, even if semiconductor chip 2 curves along the first direction and in a direction in which a center portion of semiconductor chip 2 moves away from mounting substrate 500 when semiconductor device 1 is mounted onto mounting substrate 500, an underfill material can be poured in between semiconductor chip 2 and mounting substrate 500 through the straight spaces extending in the second direction orthogonal to the first direction.

For this reason, according to semiconductor device 1 having the above configuration, the spread of the underfill material can be enhanced regardless of whether or not semiconductor chip 2 curves when semiconductor device 1 is mounted onto mounting substrate 500.

According to semiconductor device 1 having the above configuration, a relatively large number of ball-shaped bump electrodes 3 or as many ball-shaped bump electrodes 3 as possible can be provided directly above plural first source pads 111 and plural second source pads 121.

For this reason, according to semiconductor device 1 having the above configuration, an increase in resistance of a current path of current flowing through semiconductor chip 2 can be reduced and a decrease in heat dissipation of semiconductor chip 2 can be reduced after semiconductor device 1 is mounted on mounting substrate 500.

As described above, according to semiconductor device 1 having the above configuration, the spread of the underfill material after semiconductor device 1 is mounted on mounting substrate 500 can be enhanced, and at the same time, an increase in resistance of a current path of current flowing through semiconductor chip 2 can be reduced and a decrease in heat dissipation of semiconductor chip 2 can be reduced.

Thus, according to semiconductor device 1 having the above configuration, a semiconductor device that is suitable for filling a space between semiconductor chip 2 and mounting substrate 500 with the underfill material after semiconductor device 1 is mounted on mounting substrate 500 is provided.

In the plan view of semiconductor device 1, a nearest-neighbor distance of plural first linear disposition regions 71 may be at least rs/2 [μm].

Accordingly, in a state in which semiconductor device 1 is mounted facedown on mounting substrate 500, straight spaces extending in the first direction can be further provided between semiconductor chip 2 and mounting substrate 500.

In the plan view of semiconductor device 1, a diameter of each of plural first source pads 111 and plural second source pads 121 may be rs [μm].

Accordingly, in a state in which semiconductor device 1 is mounted facedown on mounting substrate 500, an increase in resistance of a current path of current flowing through semiconductor chip 2 can be further reduced, and a decrease in heat dissipation of semiconductor chip 2 can be reduced.

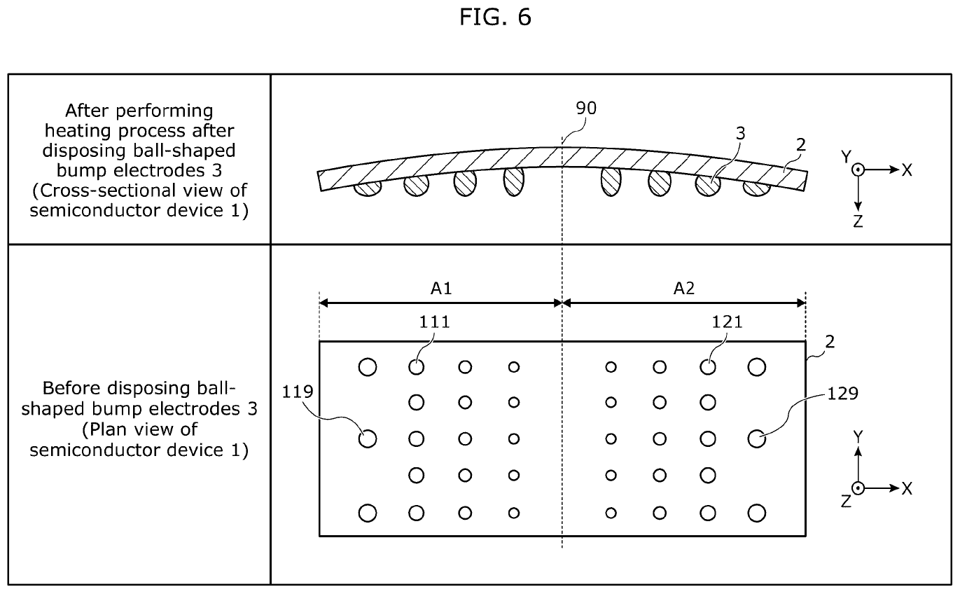

FIG. 6 is a schematic diagram illustrating a relation between the diameters of pads (first gate pad 119, plural first source pads 111, second gate pad 129, and plural second source pads 121 in FIG. 6) and heights of ball-shaped bump electrodes 3, after a heating process is performed, from the surface of semiconductor chip 2 in a third direction, when a direction orthogonal to the first direction (the X-axis direction in FIG. 6) and the second direction (the Y-axis direction in FIG. 6) is assumed to be the third direction (the Z-axis direction in FIG. 6).

Normally, a solder ball material used to provide ball-shaped bump electrodes 3 is used in the same size. For this reason, when ball-shaped bump electrodes 3 are in contact with and connected to the upper surfaces of the pads by performing a heating process, the heights of ball-shaped bump electrodes 3 from the surface of semiconductor chip 2 increase as the diameters of the pads decrease.

Thus, as illustrated in FIG. 6, when semiconductor chip 2 curves along the first direction and in a direction in which a center portion of semiconductor chip 2 moves away from mounting substrate 500, the positions of the apexes of ball-shaped bump electrodes 3 after a heating process is performed can be made relatively uniform by decreasing the diameters of pads as they are closer to boundary line 90.

Stated differently, source pads in each of plural first linear disposition regions 71 in first region A1 may have diameters that exhibit a monotonic decrease from a source pad farthest from boundary line 90 to a source pad closest to boundary line 90, and source pads in each of plural first linear disposition regions 71 in second region A2 may have diameters that exhibit a monotonic decrease from a source pad farthest from boundary line 90 to a source pad closest to boundary line 90.

Accordingly, in each of first linear disposition regions 71, the positions of the apexes in the third direction of ball-shaped bump electrodes 3 at the positions directly above the source pads can be made relatively uniform.

When the distances between the centers of the source pads are the same, the nearest-neighbor distances of the source pads become larger as the diameters of the source pads become smaller. Stated differently, in this case, the diameter of a source pad becomes smaller as the nearest-neighbor distance of the source pad becomes longer.

For this reason, source pads in each of plural first linear disposition regions 71 in first region A1 may have nearest-neighbor distances that exhibit a monotonic increase from a source pad farthest from boundary line 90 to a source pad closest to boundary line 90, and source pads in each of plural first linear disposition regions 71 in second region A2 may have nearest-neighbor distances that exhibit a monotonic increase from a source pad farthest from boundary line 90 to a source pad closest to boundary line 90.

Accordingly, in each of first linear disposition regions 71, the positions of the apexes in the third direction of ball-shaped bump electrodes 3 at the positions directly above the source pads can be made relatively uniform.

In each of second linear disposition regions 72 facing closest to each other across boundary line 90, the source pads may each have a diameter identical to a smallest diameter among diameters of plural first source pads 111 and plural second source pads 121.

Accordingly, in each of first linear disposition regions 71, the positions of the apexes in the third direction of ball-shaped bump electrodes 3 at the positions directly above the source pads can be made relatively uniform.

Ball-shaped bump electrodes 3 positioned directly above the source pads disposed in each of plural first linear disposition regions 71 include: ball-shaped bump electrodes 3 in first region A1, heights of which from the upper surface of semiconductor chip 2 may exhibit a monotonic increase from ball-shaped bump electrode 3 farthest from boundary line 90 to ball-shaped bump electrode 3 closest to boundary line 90; and ball-shaped bump electrodes 3 in second region A2, heights of which from the upper surface of semiconductor chip 2 may exhibit a monotonic increase from ball-shaped bump electrode 3 farthest from boundary line 90 to ball-shaped bump electrode 3 closest to boundary line 90.

Accordingly, in each of first linear disposition regions 71, the positions of the apexes in the third direction of ball-shaped bump electrodes 3 at the positions directly above the source pads can be made relatively uniform.

Normally, the higher the height of ball-shaped bump electrode 3 from the surface of semiconductor chip 2 is, the more the surface area of ball-shaped bump electrode 3 increases. Stated differently, the greater the surface area of ball-shaped bump electrode 3 is, the higher the height thereof from the surface of semiconductor chip 2 is.

For this reason, ball-shaped bump electrodes 3 positioned directly above the source pads disposed in each of plural first linear disposition regions 71 include: ball-shaped bump electrodes 3 in first region A1, surface areas of which may exhibit a monotonic increase from ball-shaped bump electrode 3 farthest from boundary line 90 to ball-shaped bump electrode 3 closest to boundary line 90; and ball-shaped bump electrodes 3 in second region A2, surface areas of which may exhibit a monotonic increase from ball-shaped bump electrode 3 farthest from boundary line 90 to ball-shaped bump electrode 3 closest to boundary line 90.

Accordingly, in each of first linear disposition regions 71, the positions of the apexes in the third direction of ball-shaped bump electrodes 3 at the positions directly above the source pads can be made relatively uniform.

In semiconductor device 1, current flowing through semiconductor chip 2 via source pads disposed in second linear disposition regions 72 facing closest to each other across boundary line 90 flows inside semiconductor chip 2 for the shortest distance out of the current flowing through semiconductor chip 2.

For this reason, the number of source pads disposed in each of second linear disposition regions 72 facing closest to each other across boundary line 90 may be ny. Stated differently, the number of at least two and at most ny source pads disposed in each of second linear disposition regions 72 facing closest to each other across the boundary line 90 may be ny at its maximum.

Accordingly, an increase in resistance of a current path of current flowing through semiconductor chip 2 can be reduced after semiconductor device 1 is mounted on mounting substrate 500.

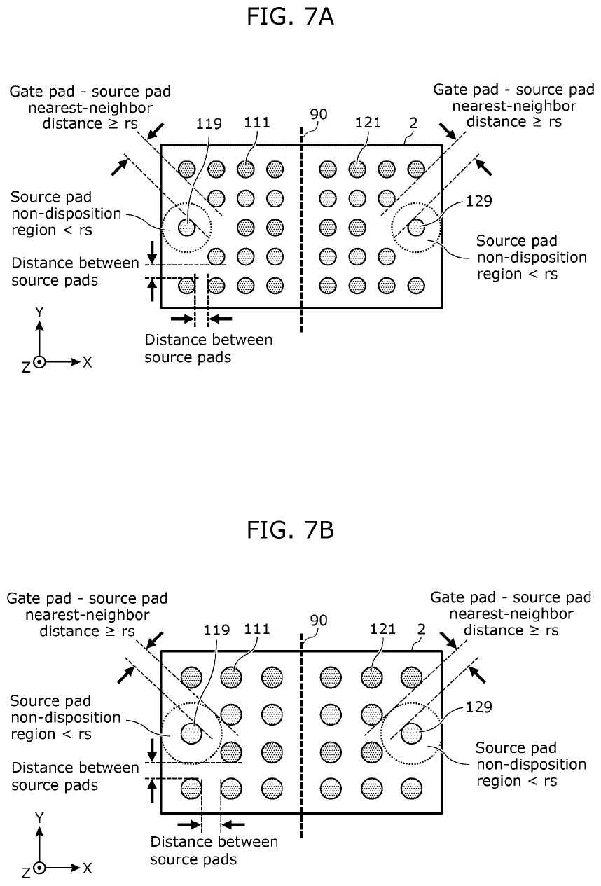

FIG. 7A and FIG. 7B are plan views each illustrating an example of a positional relation between first gate pad 119 and plural first source pads 111 and an example of a positional relation between second gate pad 129 and plural second source pads 121.

As illustrated in FIG. 7A and FIG. 7B, a distance between first gate pad 119 and first source pad 111 closest to first gate pad 119 may be at least rs [μm] and may be longer than the nearest-neighbor distance of plural first source pads 111, and a distance between second gate pad 129 and second source pad 121 closest to second gate pad 129 may be at least rs [μm] and may be longer than the nearest-neighbor distance of plural second source pads 121.

Accordingly, a short circuit between the first gate pad and any of the plural first source pads and a short circuit between the second gate pad and any of the plural second source pads can be prevented.

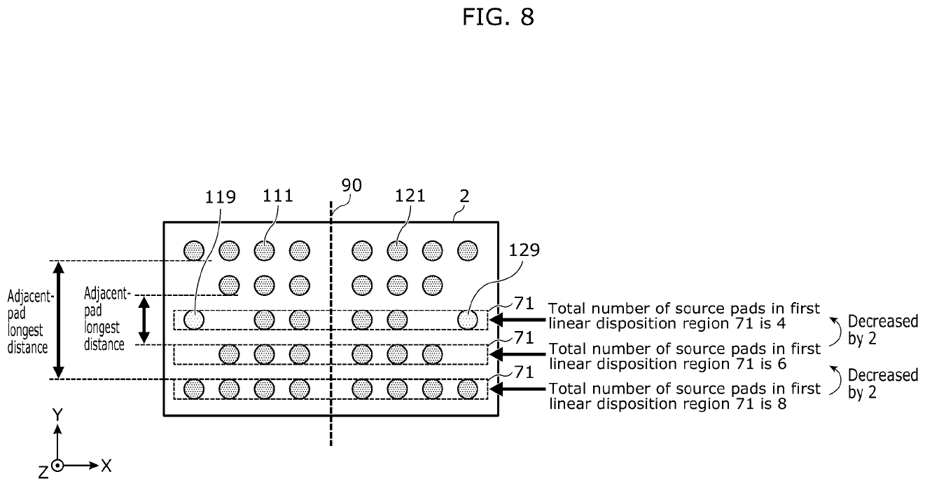

FIG. 8 is a plan view illustrating adjacent-pad longest distances that are each a longest distance among distances between adjacent source pads in each second linear disposition region 72.

As illustrated in FIG. 8, an adjacent-pad longest distance in each of plural second linear disposition regions 72 may monotonically decrease in first region A1 from second linear disposition region 72 farthest from boundary line 90 to second linear disposition region 72 closest to boundary line 90, and may monotonically decrease in second region A2 from second linear disposition region 72 farthest from boundary line 90 to second linear disposition region 72 closest to boundary line 90, and a total number of the source pads in each of plural first linear disposition regions 71 (1) may monotonically decrease in two or more first linear disposition regions 71 spaced apart from one longer side of semiconductor chip 2 by a distance shorter than a distance to the other longer side from first linear disposition region 71 closest to the one longer side to first linear disposition region 71 farthest from the one longer side, and (2) may monotonically decrease in two or more first linear disposition regions 71 spaced apart from the other longer side by a distance shorter than a distance to the one longer side from first linear disposition region 71 closest to the other longer side to first linear disposition region 71 farthest from the other longer side.

Furthermore, as illustrated in FIG. 8, the number of source pads in each of plural first linear disposition regions 71 may be decreased by two, line-by-line, with an increase in distance from the most adjacent longer side of semiconductor chip 2.

Accordingly, a short circuit between first gate pad 119 and any of plural first source pads 111 and a short circuit between second gate pad 129 and any of plural second source pads 121 can be prevented by disposing first gate pad 119 and second gate pad 129 at the positions illustrated in FIG. 8.

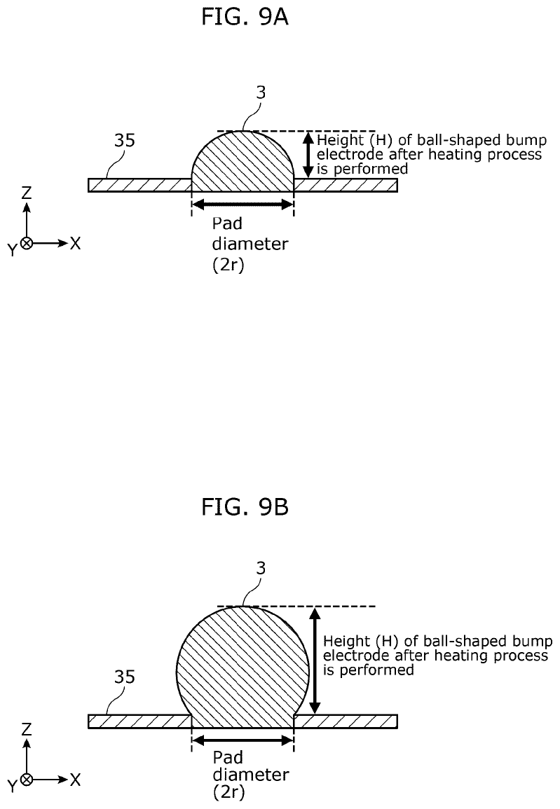

FIG. 9A and FIG. 9B are cross-sectional views illustrating examples of cross sections of ball-shaped bump electrodes 3 after a heating process is performed in the case in which ball-shaped bump electrodes 3 are in contact with and connected to the upper surface of the pads by performing a heating process.

FIG. 9A is a cross-sectional view in the case in which a cross-sectional area of ball-shaped bump electrode 3 along a plane parallel to the upper surface of semiconductor chip 2 monotonically decreases from a portion close to the upper surface of semiconductor chip 2 to a portion far therefrom.

Here, ball-shaped bump electrode 3 in the shape illustrated in FIG. 9A is also referred to as a dome-shaped bump electrode.

FIG. 9B is a cross-sectional view in the case in which a cross-sectional area of ball-shaped bump electrode 3 along a plane parallel to the upper surface of semiconductor chip 2 monotonically decreases after monotonically increasing once, from a portion close to the upper surface of semiconductor chip 2 to a portion far therefrom.

Here, ball-shaped bump electrode 3 in the shape illustrated in FIG. 9B is also referred to as a non-dome-shaped bump electrode. In the present disclosure, both of a dome-shaped bump electrode and a non-dome-shaped bump electrode are ball-shaped bump electrodes 3.

In order to avoid difficulty in manufacturing semiconductor device 1, there may be cases where ball-shaped bump electrode 3 is a dome-shaped bump electrode.

In particular, when a water-soluble film is provided on the upper surface of semiconductor chip 2 in a process after connecting ball-shaped bump electrode 3 in contact with the upper surface of a pad by performing a heating process, providing a water-soluble film is known to be difficult when ball-shaped bump electrode 3 is a non-dome-shaped bump electrode.

From the viewpoint of ensuring spreadability of the underfill material between semiconductor chip 2 and mounting substrate 500 in a state in which semiconductor device 1 is mounted on mounting substrate 500, the height of ball-shaped bump electrode 3, after a heating process is performed, from the upper surface of semiconductor chip 2 may be at least 70 [μm] and at most 130 [μm].

Assuming that the radius of a pad when ball-shaped bump electrode 3 is in contact with and connected to the upper surface of the pad by performing a heating process is r [μm] and the radius of a solder ball material before a heating process is performed is R [μm], height H [μm] of ball-shaped bump electrode 3 after a heating process from the upper surface of semiconductor chip 2 is known to be expressed by (Expression 1) below.

$$\begin{matrix}[ Math 1 ] & \\ H = \frac{{r}^{2}}{{( - 4 {R}^{3} + \sqrt{{r}^{6} + 16 {R}^{6}} )}^{\frac{1}{3}}} - {( - 4 {R}^{3} + \sqrt{{r}^{6} + 16 {R}^{6}} )}^{\frac{1}{3}} & ( Expression 1 )\end{matrix}$$

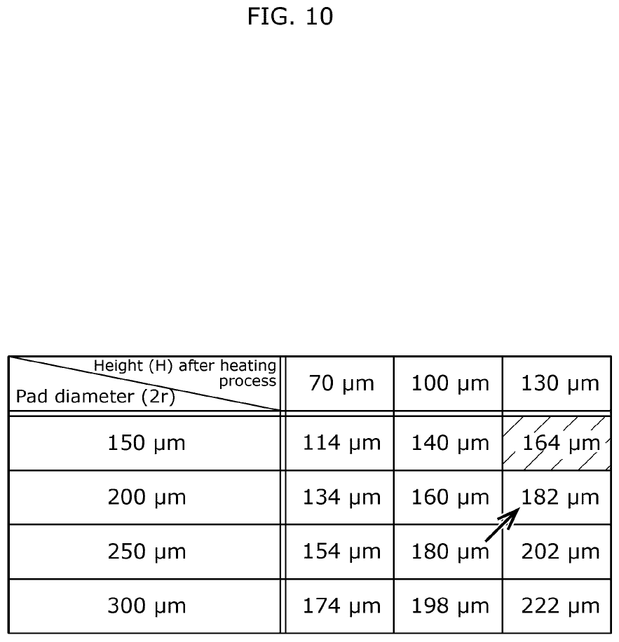

FIG. 10 is a list showing values [μm] of a diameter (=2R) of a solder ball material before a heating process is performed, which is for causing the height (=H) of ball-shaped bump electrode 3 after a heating process to be 70 [μm], 100 [μm], and 130 [μm] that are obtained by (Expression 1) when the diameter (=2r) of a pad is 150 [μm], 200 [μm], 250 [μm], and 300 [μm].

As illustrated in FIG. 10, when the diameter of a pad is 150 [μm], the diameter of the solder ball material before a heating process is 164 [μm], which is for causing ball-shaped bump electrode 3 to have a height of 130 [μm] after a heating process. Thus, in this case, ball-shaped bump electrode 3 becomes a non-dome-shaped bump electrode after the heating process.

For this reason, in a range in which ball-shaped bump electrode 3 after a heating process is a dome-shaped bump electrode, the diameter of a pad is to be greater than 150 [μm] in order that the height of ball-shaped bump electrode 3, after the heating process, from the upper surface of semiconductor chip 2 is to be a predetermined height that is at least 70 [μm] and at most 130 [μm].

Thus, rs may be greater than 150, heights of plural ball-shaped bump electrodes 3 from the upper surface of semiconductor chip 2 may be at least 70 [μm] and at most 130 [μm], and a cross-sectional area of each of plural ball-shaped bump electrodes 3 along a plane parallel to the upper surface of semiconductor chip 2 may monotonically decrease from a portion close to the upper surface of semiconductor chip 2 to a portion far therefrom.

When semiconductor chip 2 curves along the first direction that is the longer side direction of semiconductor chip 2 and in a direction in which a center portion of semiconductor chip 2 moves away from mounting substrate 500, it is known that the amount of warping of semiconductor chip 2 may be 30 [μm].

For this reason, in such a case, when the height of ball-shaped bump electrode 3 disposed directly above a pad positioned in the vicinity of a shorter side of semiconductor chip 2 is to be made 100 [μm], the diameter of a pad positioned in the vicinity of boundary line 90 may be adjusted in advance in order to cause the height of a ball disposed directly above the pad to be 130 [μm].

For this reason, in such a case, as shown by the arrow in FIG. 10, the diameter of a pad positioned in the vicinity of a shorter side of semiconductor chip 2 may be about 250 [μm], and the diameter of a pad positioned in the vicinity of boundary line 90 may be adjusted to be about 200 [μm].

Furthermore, according to the warping amount of semiconductor chip 2, the diameters of pads may be adjusted to gradually change to appropriate values in the first direction.

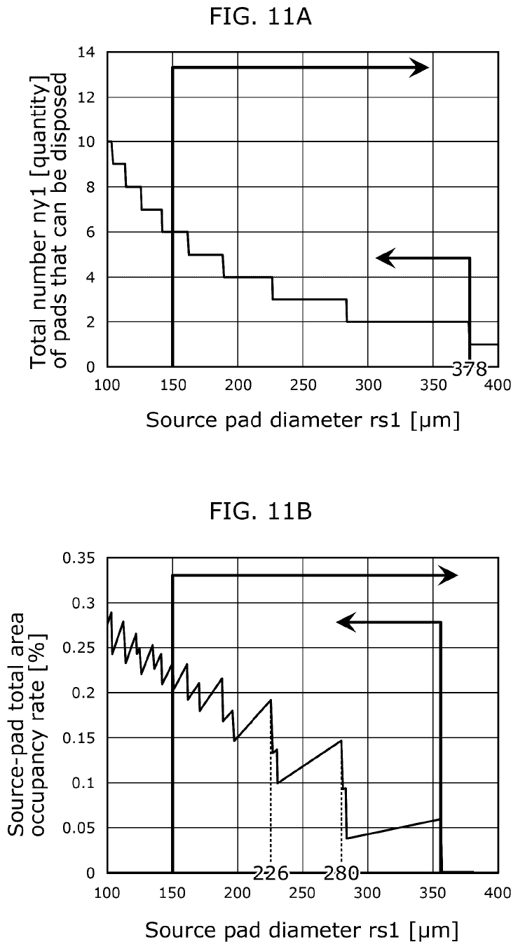

FIG. 11A is a line graph showing a relation between diameter rs1 [μm] of a source pad and total number ny1 [quantity] of source pads that can be disposed in second linear disposition region 72 when length Lx of the longer sides of semiconductor chip 2 is 3400 [μm], length Ly of the shorter sides thereof is 1960 [μm], and all the source pads have the same diameter of rs1 [μm].

As illustrated in FIG. 11A, the number of source pads that can be disposed in one second linear disposition region 72 changes stepwise, according to the diameter of the source pads.

As illustrated in FIG. 11A, when the diameter of each source pad is greater than or equal to 378 [μm], only one source pad can be disposed in one second linear disposition region 72. Stated differently, source pads cannot be disposed linearly in the second direction. For this reason, the diameter of each source pad may be less than 378 [μm].

As described above, the diameter of each source pad is to be greater than 150 [μm].

FIG. 11B is a line graph showing a relation between diameter rs1 [μm] of a source pad and an occupancy rate [%] of a total area occupied by source pads with respect to the area of the upper surface of semiconductor chip 2 when length Lx of the longer sides of semiconductor chip 2 is 3400 [μm], length Ly of the shorter sides thereof is 1960 [μm], and all the source pads have the same diameter of rs1 [μm].

In order to reduce an increase in resistance of a current path of current flowing through semiconductor chip 2 and in order to reduce a decrease in heat dissipation of semiconductor chip 2, an occupancy rate of a total area occupied by source pads of semiconductor chip 2 with respect to the surface area of the upper surface of semiconductor chip 2 may be as high as possible.

Thus, the diameter of each source pad may be 226 [μm] or 280 [μm] with which an occupancy rate of a total area occupied by source pads of semiconductor chip 2 with respect to the surface area of the upper surface of semiconductor chip 2 is maximal, as illustrated in FIG. 11B.

On the other hand, when semiconductor chip 2 is actually manufactured, the diameter of each source pad varies by about ±15 [μm] due to manufacturing variations. Thus, considering such manufacturing variations, the diameter of each source pad may be at least 196 [μm] and at most 226 [μm] or at least 250 [μm] and at most 280 [μm], in order that the diameter thereof does not exceed 226 [μm] or 280 [μm] even if manufacturing variations occur.

Furthermore, considering a possibility that semiconductor chip 2 curves along the first direction and in a direction in which the center portion thereof moves away from mounting substrate 500, among the source pads disposed in each of plural first linear disposition regions 71, a diameter of a source pad in first region A1 farthest from boundary line 90 and a diameter of a source pad in second region A2 farthest from boundary line 90 may be at least 250 [μm] and at most 280 [μm], and a diameter of a source pad in first region A1 closest to boundary line 90 and a diameter of a source pad in second region A2 closest to boundary line 90 may be at least 196 [μm] and at most 226 [μm].

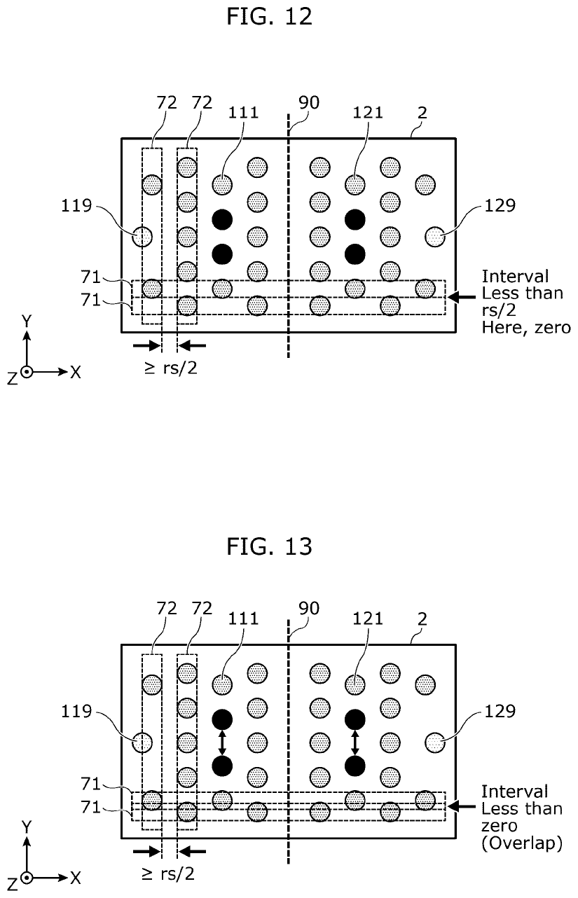

FIG. 12 is a plan view illustrating another example of a structure of semiconductor device 1. Note that FIG. 12 is a drawing from which illustration of plural ball-shaped bump electrodes 3 is omitted. For this reason, FIG. 12 is also a plan view of semiconductor chip 2.

As illustrated in FIG. 12, in the plan view of semiconductor device 1, first gate pad 119 and second gate pad 129 may not be disposed in second linear disposition regions 72.

In the plan view of semiconductor device 1, if the nearest-neighbor distance of each source pad is at least rs/2 [μm], the nearest-neighbor distance of first linear disposition regions 71 may be less than rs/2 [μm].

In the plan view of semiconductor device 1, among plural first linear disposition regions 71, positions of the source pads in the second direction (the Y-axis direction in FIG. 12) in one first linear disposition region 71 included in adjacent first linear disposition regions 71 may not coincide with positions of the source pads in the second direction in other first linear disposition region 71 included in adjacent first linear disposition regions 71.

In the plan view of semiconductor device 1, one or more source pads that are not disposed in first linear disposition regions 71 may exist. Stated differently, as illustrated in FIG. 12, in the plan view of semiconductor device 1 as shown by black source pads, for example, two source pads that are less than four source pads, whose centers are aligned linearly in the first direction (the X-axis direction in FIG. 12), may exist.

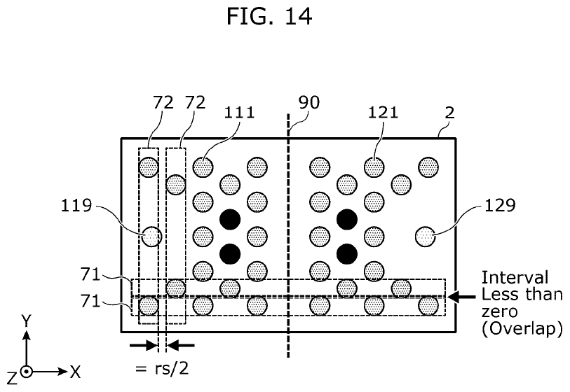

FIG. 13 is a plan view illustrating another example of a structure of semiconductor device 1. Note that FIG. 13 is a drawing from which illustration of plural ball-shaped bump electrodes 3 is omitted. For this reason, FIG. 13 is also a plan view of semiconductor chip 2.

As illustrated in FIG. 13, in the plan view of semiconductor device 1, when the nearest-neighbor distance of each source pad is at least rs/2 [μm], among plural first linear disposition regions 71, one first linear disposition region 71 and other first linear disposition region 71 of adjacent first linear disposition regions 71 may overlap.

In the plan view of semiconductor device 1, the nearest-neighbor distances between source pads adjacent to each other may not be the same in same second linear disposition region 72. Stated differently, as illustrated in FIG. 13, in the plan view of semiconductor device 1, for example, a nearest-neighbor distance between black source pads may be longer than a nearest-neighbor distance between other adjacent source pads in second linear disposition region 72 that includes the black source pads.

FIG. 14 is a plan view illustrating another example of a structure of semiconductor device 1. Note that FIG. 14 is a drawing from which illustration of plural ball-shaped bump electrodes 3 is omitted. For this reason, FIG. 14 is also a plan view of semiconductor chip 2.

As illustrated in FIG. 14, in the plan view of semiconductor device 1, a nearest-neighbor distance of second linear disposition regions 72 may be equal to rs/2 [μm].

(Supplement) The above has described the semiconductor device according to an aspect of the present disclosure, based on the embodiments, but the present disclosure is not limited to the embodiments. The scope of one or more aspects of the present disclosure may also encompass embodiments resulting from adding, to the embodiments, various modifications that may be conceived by those skilled in the art, and embodiments obtained by combining elements in different variations, as long as the resultant embodiments do not depart from the scope of the present disclosure.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The present disclosure is widely applicable to semiconductor devices, for instance.

1. A semiconductor device that is a facedown mountable, chip-size-package type semiconductor device, the semiconductor device comprising:
a semiconductor chip in a rectangular shape having longer sides extending in a first direction and shorter sides extending in a second direction in a plan view of the semiconductor device,
wherein the semiconductor chip includes:
a semiconductor layer that includes a semiconductor substrate; and
a first vertical metal-oxide semiconductor (MOS) transistor provided in the semiconductor layer in a first region and a second vertical MOS transistor provided in the semiconductor layer in a second region, the first region being one of two halves of an area of the semiconductor chip in the plan view, the second region being an other one of the two halves,
the semiconductor substrate functions as a common drain region of the first vertical MOS transistor and the second vertical MOS transistor,
a boundary line between the first region and the second region is a line segment extending in the second direction,
the first vertical MOS transistor includes a first gate pad and a plurality of first source pads in the first region in an upper surface of the semiconductor chip,
the second vertical MOS transistor includes a second gate pad and a plurality of second source pads in the second region in the upper surface of the semiconductor chip,
in the plan view, the first gate pad, the plurality of first source pads, the second gate pad, and the plurality of second source pads are each in a circular shape having a diameter less than 378 [μm],
a plurality of first linear disposition regions and a plurality of second linear disposition regions are disposed on the upper surface of the semiconductor chip in the plan view, the plurality of first linear disposition regions each being a region in which, among the plurality of first source pads and the plurality of second source pads, at least four and at most 2nx source pads are disposed with centers thereof linearly aligned in the first direction, the plurality of second linear disposition regions each being a region in which, among the plurality of first source pads or the plurality of second source pads, at least two and at most ny source pads are disposed with centers thereof linearly aligned in the second direction,
in the plan view, a width of each of the plurality of first linear disposition regions is identical to a greatest diameter among diameters of the at least four and at most 2nx source pads disposed in the first linear disposition region, and a width of each of the plurality of second linear disposition regions is identical to a greatest diameter among diameters of the at least two and at most ny source pads disposed in the second linear disposition region,
when in the plan view, a length of the longer sides is Lx [μm], a length of the shorter sides is Ly [μm], and a greatest diameter among diameters of the plurality of first source pads and the plurality of second source pads is rs [μm],
nx is a greatest integer that is at least 2 and satisfies nx<1/3×(Lx/rs−3),
ny is a greatest integer that is at least 2 and satisfies ny<2/3×(Ly/rs−1), and
in the plan view, a nearest-neighbor distance of the plurality of first source pads, a nearest-neighbor distance of the plurality of second source pads, and a nearest-neighbor distance of the plurality of second linear disposition regions are each at least rs/2 [μm], and a diameter of the first gate pad and a diameter of the second gate pad are each rs [μm],
in the plan view, the first gate pad is disposed farther from the boundary line than a second linear disposition region in the first region closest to the boundary line is, among the plurality of second linear disposition regions,
in the plan view, the second gate pad is disposed farther from the boundary line than a second linear disposition region in the second region closest to the boundary line is, among the plurality of second linear disposition regions, and
the semiconductor device further comprises a plurality of ball-shaped bump electrodes that are connected to at positions directly above and in one-to-one contact with the first gate pad, the plurality of first source pads, the second gate pad, and the plurality of second source pads.

2. The semiconductor device according to claim 1,
wherein a nearest-neighbor distance of the plurality of first linear disposition regions is at least rs/2 [μm] in the plan view.

3. The semiconductor device according to claim 1,
wherein a diameter of each of the plurality of first source pads and the plurality of second source pads is rs [μm] in the plan view.

4. The semiconductor device according to claim 1,
wherein in the plan view, among the at least four and at most 2nx source pads in each of the plurality of first linear disposition regions,
source pads in the first region have diameters that exhibit a monotonic decrease from a source pad farthest from the boundary line to a source pad closest to the boundary line, and
source pads in the second region have diameters that exhibit a monotonic decrease from a source pad farthest from the boundary line to a source pad closest to the boundary line.

5. The semiconductor device according to claim 4,
wherein in the plan view, among the at least four and at most 2nx source pads in each of the plurality of first linear disposition regions,
source pads in the first region have nearest-neighbor distances that exhibit a monotonic increase from a source pad farthest from the boundary line to a source pad closest to the boundary line, and
source pads in the second region have nearest-neighbor distances that exhibit a monotonic increase from a source pad farthest from the boundary line to a source pad closest to the boundary line.

6. The semiconductor device according to claim 1,
wherein in the plan view, in each of second linear disposition regions facing closest to each other across the boundary line among the plurality of second linear disposition regions, the at least two and at most ny source pads each have a diameter identical to a smallest diameter among diameters of the plurality of first source pads and the plurality of second source pads.

7. The semiconductor device according to claim 1,
wherein in the plan view, among the plurality of ball-shaped bump electrodes, ball-shaped bump electrodes positioned directly above the at least four and at most 2nx source pads disposed in each of the plurality of first linear disposition regions include:
ball-shaped bump electrodes in the first region, heights of which from the upper surface of the semiconductor chip exhibit a monotonic increase from a ball-shaped bump electrode farthest from the boundary line to a ball-shaped bump electrode closest to the boundary line; and
ball-shaped bump electrodes in the second region, heights of which from the upper surface of the semiconductor chip exhibit a monotonic increase from a ball-shaped bump electrode farthest from the boundary line to a ball-shaped bump electrode closest to the boundary line.

8. The semiconductor device according to claim 1,
wherein in the plan view, among the plurality of ball-shaped bump electrodes, ball-shaped bump electrodes positioned directly above the at least four and at most 2nx source pads disposed in each of the plurality of first linear disposition regions include:
ball-shaped bump electrodes in the first region, surface areas of which exhibit a monotonic increase from a ball-shaped bump electrode farthest from the boundary line to a ball-shaped bump electrode closest to the boundary line; and
ball-shaped bump electrodes in the second region, surface areas of which exhibit a monotonic increase from a ball-shaped bump electrode farthest from the boundary line to a ball-shaped bump electrode closest to the boundary line.

9. The semiconductor device according to claim 3,
wherein in the plan view, a total number of the at least two and at most ny source pads disposed in each of second linear disposition regions facing closest to each other across the boundary line among the plurality of second linear disposition regions is ny.

10. The semiconductor device according to claim 9,
wherein in the plan view,
a distance between the first gate pad and a first source pad closest to the first gate pad among the plurality of first source pads is at least rs [μm] and is longer than the nearest-neighbor distance of the plurality of first source pads, and
a distance between the second gate pad and a second source pad closest to the second gate pad among the plurality of second source pads is at least rs [μm] and is longer than the nearest-neighbor distance of the plurality of second source pads.

11. The semiconductor device according to claim 10,
wherein in the plan view,
an adjacent-pad longest distance that is a longest distance among distances between pairs of adjacent source pads included in the at least two and at most ny source pads in each of the plurality of second linear disposition regions monotonically decreases in the first region from a second linear disposition region farthest from the boundary line to a second linear disposition region closest to the boundary line among the plurality of second linear disposition regions, and monotonically decreases in the second region from a second linear disposition region farthest from the boundary line to a second linear disposition region closest to the boundary line among the plurality of second linear disposition regions, and
a total number of the at least four and at most 2nx source pads in each of the plurality of first linear disposition regions (1) monotonically decreases in, among the plurality of first linear disposition regions, two or more first linear disposition regions spaced apart from one longer side out of the longer sides by a distance shorter than a distance to an other longer side out of the longer sides from a first linear disposition region closest to the one longer side to a first linear disposition region farthest from the one longer side, and (2) monotonically decreases in, among the plurality of first linear disposition regions, two or more first linear disposition regions spaced apart from the other longer side by a distance shorter than a distance to the one longer side from a first linear disposition region closest to the other longer side to a first linear disposition region farthest from the other longer side.

12. The semiconductor device according to claim 1,
wherein in the plan view,
among the plurality of first linear disposition regions, positions of the at least four and at most 2nx source pads in the second direction in one first linear disposition region included in adjacent first linear disposition regions do not coincide with positions of the at least four and at most 2nx source pads in the second direction in an other first linear disposition region included in the adjacent first linear disposition regions.

13. The semiconductor device according to claim 3,
wherein rs is at least 196 and at most 226 or at least 250 and at most 280.

14. The semiconductor device according to claim 4,
wherein in the plan view, among the at least four and at most 2nx source pads disposed in each of the plurality of first linear disposition regions, a diameter of a source pad in the first region farthest from the boundary line and a diameter of a source pad in the second region farthest from the boundary line are at least 250 [μm] and at most 280 [μm], and a diameter of a source pad in the first region closest to the boundary line and a diameter of a source pad in the second region closest to the boundary line are at least 196 [μm] and at most 226 [μm].

15. The semiconductor device according to claim 1,
wherein rs is greater than 150,
a height of each of the plurality of ball-shaped bump electrodes from the upper surface of the semiconductor chip is at least 70 [μm] and at most 130 [μm], and
a cross-sectional area of each of the plurality of ball-shaped bump electrodes along a plane parallel to the upper surface of the semiconductor chip monotonically decreases from a cross-section of the ball-shaped bump electrode close to the upper surface of the semiconductor chip to a cross-section of the ball-shaped bump electrode far from the upper surface of the semiconductor chip.
